(19) United States
(12) Patent Application Publication
(10) Pub. No.: US 2015/0090896 A1
(43) Pub. Date: Apr. 2, 2015

(54) DRAWING APPARATUS, AND METHOD OF MANUFACTURING ARTICLE

(71) Applicant: CANON KABUSHIKI KAISHA, Tokyo (JP)

(72) Inventors: Go TSUCHIYA, Tochigi-shi (JP); Kazuya KIKUCHI, Utsunomiya-shi (JP)

(21) Appl. No.: 14/488,710

(22) Filed: Sep. 17, 2014

(30) Foreign Application Priority Data
Sep. 30, 2013 (JP) 2013-205351

(51) Int. Cl. H01J 37/04; H01J 37/302; H01J 37/317

(52) U.S. Cl. CPC H01J 37/045; H01J 37/3177; H01J 37/3023; H01J 2237/12; H01J 2237/0435; H01J 2237/31798
USPC 250/397; 250/396 R

(57) ABSTRACT

The present invention provides a drawing apparatus which performs drawing on a substrate with a plurality of charged particle beams, the apparatus comprising two blanker arrays each including a plurality of first blankers which blank a plurality of charged particle beams individually and a plurality of second blankers which blank a plurality of charged particle beams in common, wherein the plurality of first blankers and the plurality of second blankers in each of the two blanker arrays are arranged such that one of the plurality of charged particle beams passes through corresponding one of the plurality of first blankers of one of the two blanker arrays and corresponding one of the plurality of second blankers of the other of the two blanker arrays.

### BACKGROUND OF THE INVENTION

1. Field of the Invention

The present invention relates to a drawing apparatus, and a method of manufacturing an article.

2. Description of the Related Art

Along with micropatterning and high integration of circuit patterns in semiconductor integrated circuits, attention is paid to a drawing apparatus which draws a pattern on a substrate with a plurality of charged particle beams (electron beams). The drawing apparatus includes a blanker array having a plurality of blankers to deflect the plurality of charged particle beams individually. Signal lines which transmit control signals to control the blankers are connected to them, respectively.

In the drawing apparatus thus configured, when, for example, disconnection (breaking of wire) occurs in the signal lines, the blankers to which the disconnected signal lines are connected cannot deflect the charged particle beams. That is, a substrate is continuously irradiated with the charged particle beams that should be blanked by the blankers, resulting in defect occurrence in a pattern formed on the substrate. To solve this, Japanese Patent No. 4313145 has proposed a drawing apparatus in which a plurality of blanker arrays are provided, and each of them can perform blanking of one charged particle beam.

In the drawing apparatus described in Japanese Patent No. 4313145, a signal line is connected to each of the plurality of blankers in one blanker array, and blanking of the charged particle beam in each of the plurality of blankers is controlled individually. In recent years, however, throughput improvement is required of the drawing apparatus. To meet the requirement, the number of charged particle beams is dramatically increasing. As the number of charged particle beams thus increases, the space between the plurality of blankers in one blanker array is reduced. This may make it difficult to connect the signal lines to the respective blankers individually.

### SUMMARY OF THE INVENTION

The present invention provides, for example, a drawing apparatus advantageous in terms of individual blanking of a plurality of charged particle beams.

According to one aspect of the present invention, there is provided a drawing apparatus which performs drawing on a substrate with a plurality of charged particle beams, the apparatus comprising: two blanker arrays each including a plurality of first blankers which blank a plurality of charged particle beams individually and a plurality of second blankers which blank a plurality of charged particle beams in common; wherein the plurality of first blankers and the plurality of second blankers in each of the two blanker arrays are arranged such that one of the plurality of charged particle beams passes through corresponding one of the plurality of first blankers of one of the two blanker arrays and corresponding one of the plurality of second blankers of the other of the two blanker arrays.

Further features of the present invention will become apparent from the following description of exemplary embodiments with reference to the attached drawings.

### BRIEF DESCRIPTION OF THE DRAWINGS

FIG. 1 is a view showing a drawing apparatus according to the first embodiment;

FIG. 2A is a view showing an example of the arrangement of a blanker array according to the first embodiment;

FIG. 2B is a view showing an example of the arrangement of a blanker array according to the first embodiment;

FIG. 3 is a flowchart showing a method of performing drawing on a substrate in the drawing apparatus according to the first embodiment;

FIG. 4A is a view showing an example of the arrangement of the blanker array according to the first embodiment;

FIG. 4B is a view showing an example of the arrangement of the blanker array according to the first embodiment;

FIG. 5A is a view showing an example of the arrangement of a blanker array according to the second embodiment; and

FIG. 5B is a view showing an example of the arrangement of the blanker array according to the second embodiment.

### DESCRIPTION OF THE EMBODIMENTS

Exemplary embodiments of the present invention will be described below with reference to the accompanying drawings. Note that the same reference numerals denote the same members throughout the drawings, and a repetitive description thereof will not be given.

### First Embodiment

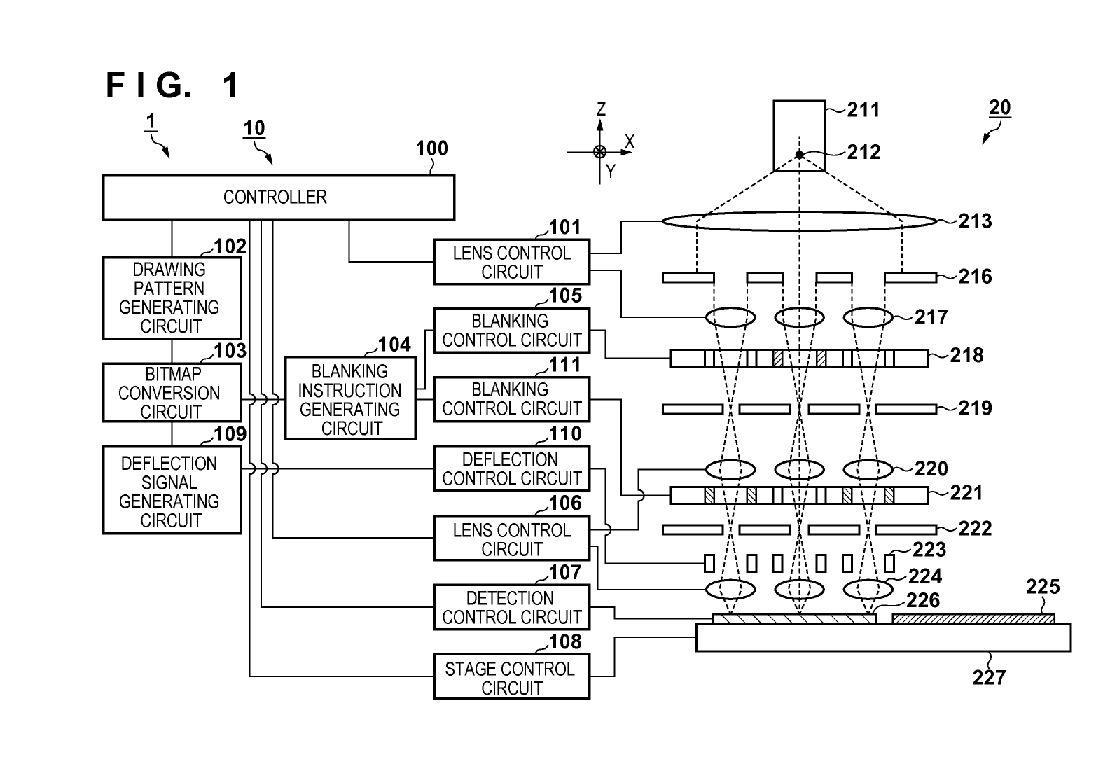

A drawing apparatus 1 according to the first embodiment of the present invention will be described with reference to FIG. 1. The drawing apparatus 1 according to the first embodiment includes a drawing unit 20 which draws a pattern by irradiating a substrate 225 with a charged particle beam, and a control unit 10 (controller) which controls the respective units of the drawing unit 20. The drawing unit 20 includes, for example, a charged particle source 211, a collimator lens 213, an aperture array 216, a first electrostatic lens 217, a first blanker array 218, and first blanking apertures 219 (aperture members). The drawing unit 20 also includes a second electrostatic lens 220, a second blanker array 221, second blanking apertures 222 (aperture members), deflectors 223, an objective lens 224, a detection unit 226 (detector), and a substrate stage 227.

A charged particle beam emitted from the charged particle source 211 forms a cross-over image 212, changes to a parallel beam by the effect of the collimator lens 213, and enters the aperture array 216. The aperture array 216 has a plurality of openings arrayed in a matrix. The charged particle beam that has entered as the parallel beam is thus divided into a plurality of beams. The plurality of charged particle beams divided by the aperture array 216 enter the first electrostatic lens 217. The first electrostatic lens 217 is formed by, for example, three electrode plates (these three electrode plates are shown as an integrated electrode plate in FIG. 1) having circular apertures. The charged particle beams that have passed through the first electrostatic lens 217 form intermediate images of the cross-over image 212. The first blanking aperture 219 having openings arranged in a matrix is arranged on the plane where the intermediate images are formed. The first blanker array 218 including a plurality of blankers which individually deflect the respective charged particle beams is arranged between the first electrostatic lens 217 and the first blanking aperture 219. Each blanker is formed from, for example, two facing electrodes. The blanker generates an electric field by applying a voltage between the two electrodes, and can deflect a charged particle beam. The charged particle beams deflected by the blankers in the first blanker array 218 are shielded by the first blanking aperture 219 and do not reach the substrate. That is, the first blanker array 218 switches between irradiation and non-irradiation of the substrate 225 with the charged particle beams.

The plurality of charged particle beams that have passed through the first blanking aperture 219 enter the second electrostatic lens 220. The second electrostatic lens 220 is formed by, for example, three electrode plates (these three electrode plates are shown as an integrated electrode plate in FIG. 1) having circular apertures in the same manner as the first electrostatic lens 217. The charged particle beams that have passed through the second electrostatic lens 220 form intermediate images of the cross-over image 212. The second blanking aperture 222 having openings arranged in a matrix is arranged on the plane where the intermediate images are formed. The second blanker array 221 including a plurality of blankers which individually deflect the respective charged particle beams is arranged between the second electrostatic lens 220 and the second blanking aperture 222. The charged particle beams deflected by the blankers in the second blanker array 221 are shielded by the second blanking aperture 222 and do not reach the substrate. That is, the second blanker array 221 switches between irradiation and non-irradiation of the substrate 225 with the charged particle beams in the same manner as the first blanker array 218.

The charged particle beams that have passed through the second blanking aperture 222 form, through the deflectors 223 to scan the charged particle beams on the substrate and the objective lens 224, the images of the cross-over image 212 on the substrate held on the substrate stage 227. While drawing a pattern on the substrate 225, the substrate 225 continuously moves, for example, in the Y direction by the substrate stage 227, and the images formed on the substrate are scanned, for example, in the X direction by the deflectors 223. During this time, deflection of each charged particle beam by the first blanker array 218 and the second blanker array 221 is controlled in accordance with the pattern formed on the substrate, and irradiation and non-irradiation of the substrate 225 with the respective charged particle beams are repeated. The direction in which the charged particle beams are deflected by the deflectors 223 may be perpendicular to the moving direction of the substrate stage 227. However, the deflection direction is not limited to this as long as it is different from the moving direction of the substrate stage 227. The detection unit 226 which detects the plurality of charged particle beams that have passed thorough the objective lens 224 is provided on the substrate stage 227.

The control unit 10 includes, for example, a drawing pattern generating circuit 102, a bitmap conversion circuit 103, a blanking instruction generating circuit 104, and a deflection signal generating circuit 109. The control unit 10 also includes lens control circuits 101 and 106, blanking control circuits 105 and 111, a deflection control circuit 110, a stage control circuit 108, a detection control circuit 107, and a controller 100. The drawing pattern generating circuit 102 generates pattern data to be drawn on the substrate. The bitmap conversion circuit 103 converts the pattern data generated by the drawing pattern generating circuit into bitmap data. The blanking instruction generating circuit 104 generates, based on the bitmap data converted by the bitmap conversion circuit, a plurality of control data to control the first blanker array 218 and the second blanker array 221. The deflection signal generating circuit 109 generate, based on the bitmap data converted by the bitmap conversion circuit, a deflection signal to control the deflectors 223.

The lens control circuits 101 and 106 control the first electrostatic lens 217, the second electrostatic lens 220, and the objective lens 224. The blanking control circuit 105 generates, based on the control data generated by the blanking instruction generating circuit 104, control signals to control the respective blankers in the first blanker array 218, and controls the first blanker array 218 by those control signals. The blanking control circuit 111 generates, based on the control data generated by the blanking instruction generating circuit 104, control signals to control the respective blankers in the second blanker array 221, and controls the second blanker array 221 by those control signals. The deflection control circuit 110 controls the deflectors 223 based on the deflection signal generated by the deflection signal generating circuit 109. The detection control circuit 107 controls the detection unit 226, and determines the control state of each charged particle beam in the drawing unit 20 based on the detection result of the detection unit 226. The stage control circuit 108 controls the movement of the substrate stage 227. The controller 100 controls the respective circuits included in the control unit 10, and integrates all drawing operations in the drawing apparatus 1.

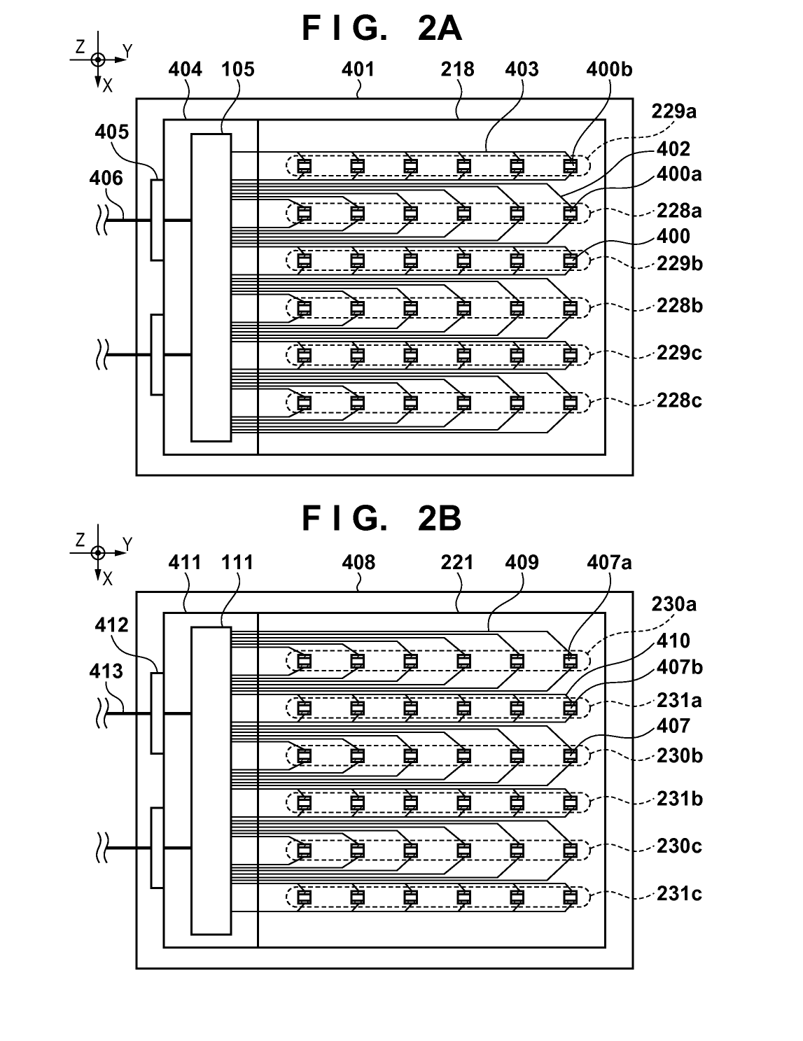

The drawing apparatus generally includes a blanker array having a plurality of blankers to deflect a plurality of charged particle beams individually. Signal lines which transmit control signals to control the blankers are connected to them, respectively. However, when, for example, disconnection (breaking of wire) occurs in the signal lines, the blankers to which the disconnected signal lines are connected cannot deflect the charged particle beams. That is, a substrate is continuously irradiated with the charged particle beams that should be blanked by the blankers, resulting in the cause of a defect in a pattern formed on the substrate. To solve this, a plurality (two) of blanker arrays (the first blanker array 218 and the second blanker array 221) are provided in the drawing apparatus 1 according to the first embodiment, as described above. The arrangements of the first blanker array 218 and the second blanker array 221 will be described below with reference to FIGS. 2A and 2B. FIGS. 2A and 2B are views each showing an example of the arrangement of the blanker array. In FIGS. 2A and 2B, 36 (6×6) blankers are arranged in each of the first blanker array 218 and the second blanker array 221, for the sake of simplicity. In practice, however, several tens of thousands to several millions of blankers are arranged to correspond to several tens of thousands to several millions of charged particle beams. In FIGS. 2A and 2B, the first direction is defined as the Y direction, and the second direction is defined as the X direction. However, the present invention is not limited to this, and the first direction may be defined as the X direction and the second direction may be defined as the Y direction, for example.

FIG. 2A is the view showing the example of the arrangement of the first blanker array 218. FIG. 2A illustrates a structure 401 which supports the first blanker array 218, and the blanking control circuit 105 which controls a plurality of blankers 400 in the first blanker array 218. FIG. 2A also illustrates a wiring board 404 serving as a wiring relay between the first blanker array 218 and the blanking control circuit 105. The blanking control circuit 105 is connected to the blanking instruction generating circuit 104 via a connector 405 and a cable 406.

The first blanker array 218 can include a substrate which includes a plurality of first blanker lines 228a to 228c and a plurality of second blanker lines 229a to 229c. Each first blanker line 228 includes a plurality of first blankers 400a which blank the plurality of charged particle beams individually, and each second blanker line 229 includes a plurality of second blankers 400b which blank the plurality of charged particle beams in common. In the first blanker lines 228, the plurality of first blankers 400a are arrayed along the first direction (Y direction). Signal lines 402 which transmit the control signals generated by the blanking control circuit 105 are connected to the plurality of first blankers 400a individually. The plurality of second blankers 400b in the second blanker lines 229 are arrayed along the first direction (Y direction). A signal line 403 which transmits the control signals is connected to the plurality of second blankers 400b in the second blanker lines 229 in common. The plurality of first blanker lines 228a to 228c and the plurality of second blanker lines 229a to 229c are apart from each other and arranged alternately in the second direction (for example, the X direction) crossing the first direction.

FIG. 2B is the view showing the example of the arrangement of the second blanker array 221. FIG. 2B illustrates a structure 408 which supports the second blanker array 221, and the blanking control circuit 111 which controls a plurality of blankers 407 in the second blanker array 221. FIG. 2B also illustrates a wiring board 411 serving as a wiring relay between the second blanker array 221 and the blanking control circuit 111. The blanking control circuit 111 is connected to the blanking instruction generating circuit 104 via a connector 412 and a cable 413.

The second blanker array 221 can include a substrate which includes a plurality of first blanker lines 230a to 230c and a plurality of second blanker lines 231a to 231c as in the first blanker array 218. Each first blanker line 230 includes a plurality of first blankers 407a which blank the plurality of charged particle beams individually, and each second blanker line 231 includes a plurality of second blankers 407b which blank the plurality of charged particle beams in common. In the first blanker lines 230, the plurality of first blankers 407a are arrayed along the first direction (Y direction). Signal lines 409 which transmit the control signals generated by the blanking control circuit 105 are connected to the plurality of first blankers 407a individually. The plurality of second blankers 407b in the second blanker lines 231 are arrayed along the first direction (Y direction). A signal line 410 which transmits the control signals is connected to the plurality of second blankers 407b in the second blanker lines 231 in common. In contrast to the first blanker array 218, the first blanker lines 230 and the second blanker lines 231 change places in the second blanker array 221. This makes it possible to cause each charged particle beam to pass through the first blankers of the first blanker lines provided in one of two blanker arrays and the second blankers of the second blanker lines provided in the other blanker array. That is, it is possible to cause each charged particle beam that has passed through the first blankers 400a of the first blanker lines 228 in the first blanker array 218 to pass through the second blankers 407b of the second blanker lines 231 in the second blanker array 221. On the other hand, it is possible to cause each charged particle beam that has passed through the second blankers 400b of the second blanker lines 229 in the second blanker array 218 to pass through the first blankers 407a of the first blanker lines 230 in the second blanker array 221.

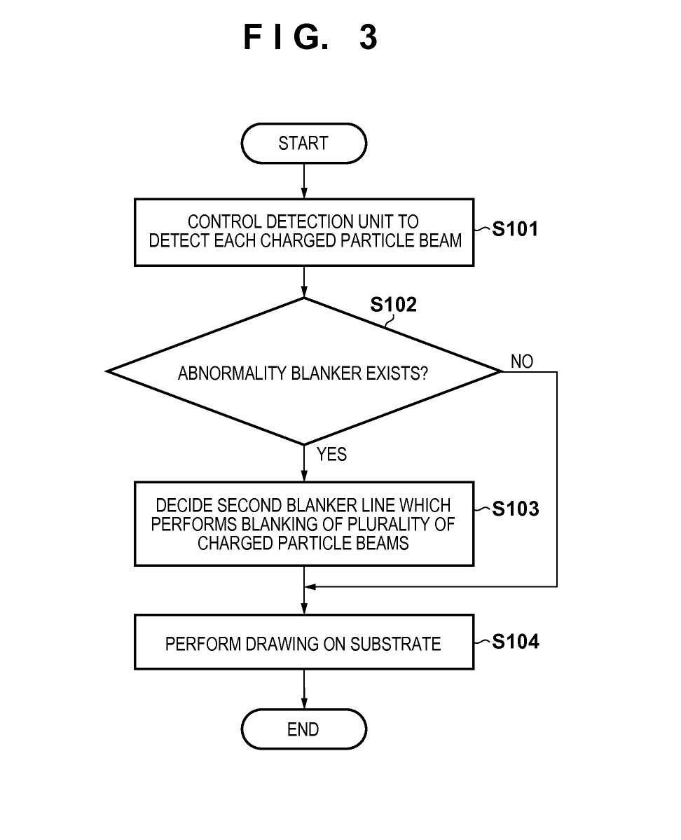

The drawing apparatus 1 thus configured according to the first embodiment typically deflects the respective charged particle beams by the first blankers of the first blanker lines in the first blanker array 218 and the second blanker array 221, and performs blanking of the respective charged particle beams. For example, the first blanker lines in one of two blanker arrays may include the first blanker (to be referred to as an abnormal blanker) with an abnormality such as signal line disconnection in blanking of the charged particle beams. In this case, the drawing apparatus 1 drives the plurality of second blankers of the second blanker lines in the other blanker array in common so as not to irradiate the substrate 225 with the charged particle beams that should be blanked by the abnormal blanker. This allows the drawing apparatus 1 to prevent the substrate 225 from being continuously irradiated with the charged particle beams that should be blanked by the abnormal blanker, and suppress defect occurrence in the pattern formed on the substrate. A method of performing drawing on the substrate 225 in the drawing apparatus 1 according to the first embodiment will now be described with reference to FIG. 3. FIG. 3 is a flowchart showing the method of performing drawing on the substrate 225 in the drawing apparatus 1 according to the first embodiment.

In step S101, the control unit 10 controls the detection unit 226 to detect the respective charged particle beams while controlling the respective first blankers (400a and 407a) of the first blanker lines (228 and 230) in the first blanker array 218 and the second blanker array 221. For example, the control unit 10 sets a state in which the respective second blankers (400b and 407b) of the second blanker lines (229 and 231) in the first blanker array 218 and the second blanker array 221 are not driven (a state in which no voltage is applied to two electrodes). That is, the control unit 10 sets a state in which the respective second blankers (400b and 407b) of the second blanker lines (229 and 231) do not perform blanking of the charged particle beams. Then, in that state, the control unit 10 controls to drive (a voltage is applied to two electrodes) the respective first blankers (400a and 407a) in the first blanker array 218 and the second blanker array 221, and controls the detection unit 226 to detect the charged particle beams. At this time, if no charged particle beams are detected by the detection unit 226, the respective first blankers (400a and 407a) in the first blanker array 218 and the second blanker array 221 operate normally. On the other hand, if the charged particle beams are detected by the detection unit 226, some abnormality occurs in the first blankers which deflect the detected charged particle beams. That is, the control unit 10 can specify the abnormal blanker with the abnormality in blanking of the charged particle beams (which cannot perform blanking of the charged particle beams) based on the output from the detection unit 226.

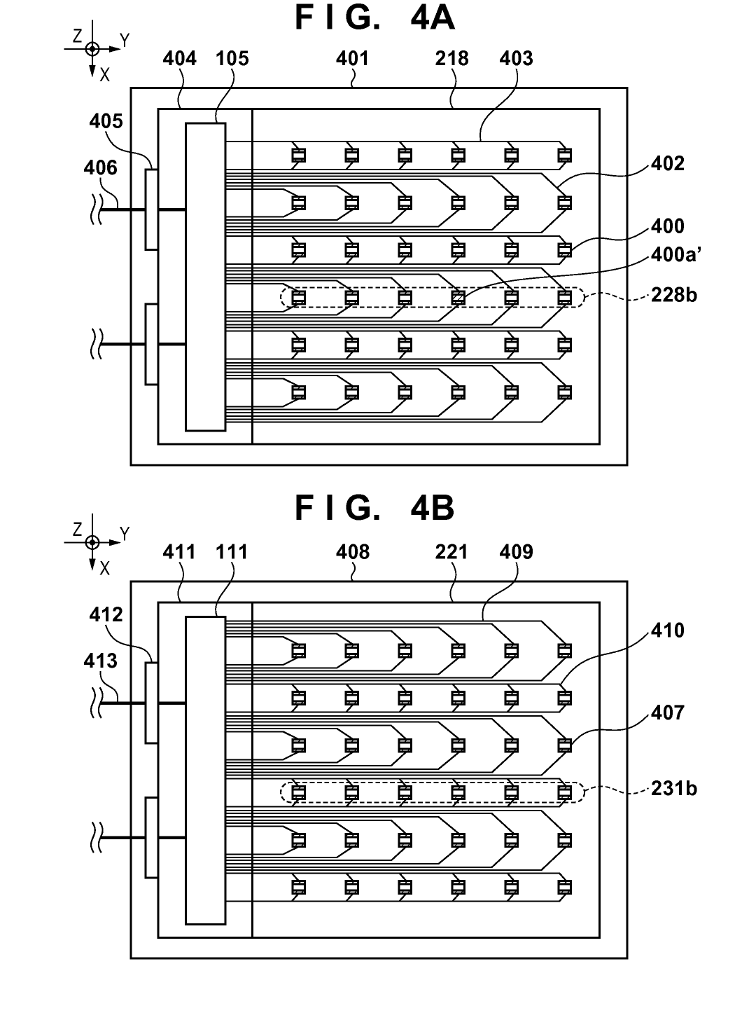

In step S102, the control unit 10 determines whether an abnormal blanker exists in the first blanker lines in the first blanker array 218 and the second blanker array 221. If the abnormal blanker exists, the process advances to step S103. If no abnormal blanker exists, the process advances to step S104. In step S103, the control unit 10 drives the plurality of second blankers in common, and decides the second blanker lines which perform blanking of the plurality of charged particle beams based on the position of the abnormal blanker. As shown in FIG. 4A, for example, assume that a first blanker 400a′ of the first blanker line 228b in the first blanker array 218 is an abnormal blanker with an abnormality in blanking of the charged particle beams. In this case, the control unit 10 decides, in the second blanker array 221, the second blanker lines 231 which drive the plurality of second blankers 407b corresponding to abnormal blankers in common based on the position of the abnormal blanker (the blanker 400a). In a case shown in FIG. 4B, the control unit 10 decides the second blanker lines 231 which drive the plurality of second blankers 407b in common as the second blanker line 231b.

In step S104, the control unit 10 performs drawing on the substrate 225 with the plurality of charged particle beams. If the control unit 10 determines that the abnormal blanker exists in step S102, drawing is performed on the substrate 225 in a state in which the plurality of second blankers 407b of the second blanker line 231b decided in step S103 is driven. That is, the plurality of charged particle beams which are blanked by the plurality of second blankers 407b of the second blanker line 231b decided in step S103 are not used when performing drawing on the substrate 225. As a result, by controlling the plurality of second blankers 407b of the second blanker line 231b decided in step S103 in common, a region where no drawing is performed may be present on the substrate. In this case, the control unit 10 can control a drawing operation such that drawing is performed in the region where no drawing has not been performed with, for example, a charged particle beam which is different from the plurality of charged particle beams blanked by the second blanker line 231b.

As described above, the drawing apparatus 1 according to the first embodiment includes the first blanker array 218 and the second blanker array 221 each having the first blanker lines and the second blanker lines. The first blanker lines include the plurality of first blankers which blank the plurality of charged particle beams individually. The second blanker lines include the plurality of second blankers which blank the plurality of charged particle beams in common. The first blanker lines and the second blanker lines in the respective blanker arrays are arranged such that the respective charged particle beams pass through the first blankers of the first blanker lines and the second blankers of the second blanker lines provided in the different blanker arrays. This makes it possible to perform blanking of the charged particle beams which have not undergone blanking because of the abnormal blanker of the first blanker line in one blanker array by controlling the plurality of second blankers of the second blanker line in the other blanker array. Hence, it is possible to prevent the substrate from being irradiated with the charged particle beams which have not undergone blanking because of the abnormal blanker, and suppress defect occurrence in the pattern formed on the substrate. The drawing apparatus 1 according to the first embodiment uses two blanker arrays, namely the first blanker array 218 and the second blanker array 221. However, the present invention is not limited to this, and the drawing apparatus 1 may use three or more blanker arrays. In this case as well, each blanker array may be formed to include the first blanker lines and the second blanker lines.

### Second Embodiment

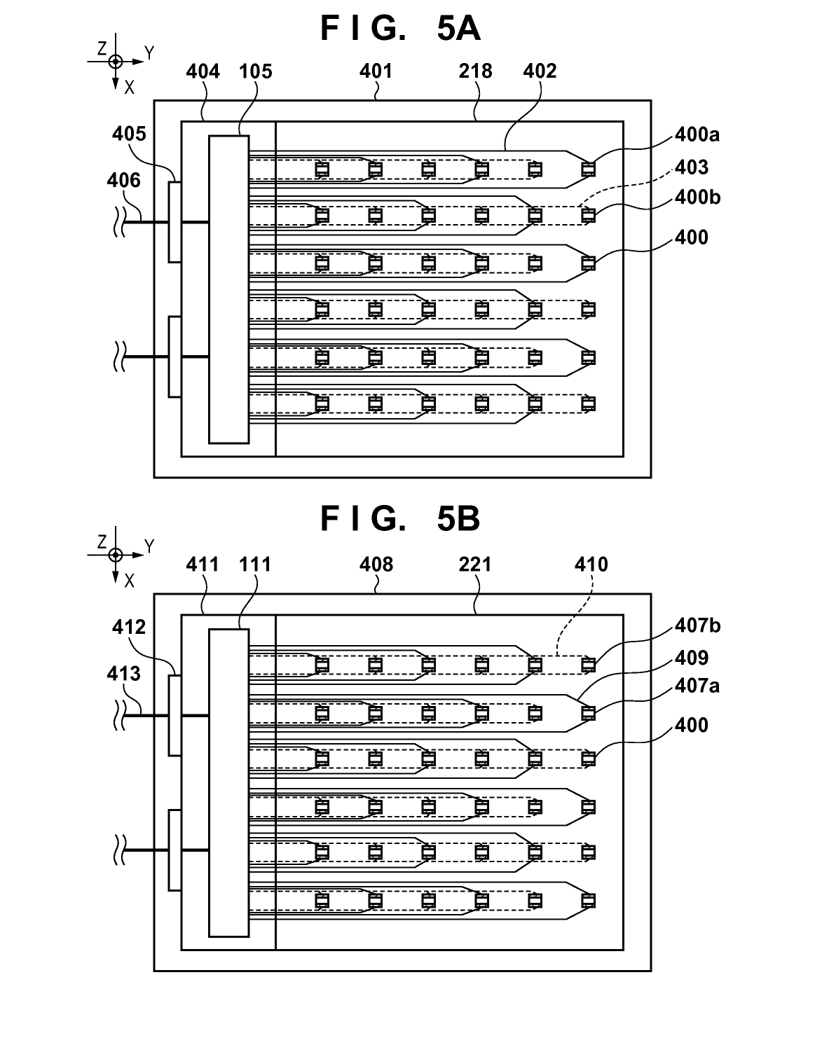

In the second embodiment, other examples of the arrangement of a blanker array will be described with reference to FIGS. 5A and 5B. FIGS. 5A and 5B are views showing the other examples of the arrangement of the blanker array.

FIG. 5A is the view showing the other example of the arrangement of a first blanker array 218. In the first blanker array 218 shown in FIG. 5A, a plurality of first blankers 400a and a plurality of second blankers 400b are alternately arranged along the X and Y directions, respectively. Signal lines 402 which transmit control signals generated by a blanking control circuit 105 are connected to the plurality of first blankers 400a individually. A signal line 403 which transmits the control signals is connected to the plurality of second blankers 400b in common. The signal lines 402 connected to the respective first blankers 400a and the signal line 403 connected to the respective second blankers 400b form a multilayer wiring in a substrate. In FIG. 5A, the signal line 403 connected to the respective second blankers 400b is set as a lower-layer wiring. However, the present invention is not limited to this, and the signal lines 402 connected to the respective first blankers 400a may be set as the lower-layer wiring.

FIG. 5B is the view showing the other example of the arrangement of a second blanker array 221. In the second blanker array 221 shown in FIG. 5B, a plurality of first blankers 407a and a plurality of second blankers 407b are alternately arranged along the X and Y directions, respectively. In contrast to the first blanker array 218, the first blankers 407a and the second blankers 407b are arranged conversely in the second blanker array 221. This makes it possible to cause each charged particle beam to pass through the first blanker (400a or 407a) and the second blanker (400b or 407b) provided in one of two blanker arrays. In FIGS. 5A and 5B, the first blankers and the second blankers are arranged alternately one by one along the X and Y directions in the respective blanker arrays. However, the present invention is not limited to this, and the first blankers and the second blankers may be arranged alternately every plurality of blankers.

### Embodiment of Article Manufacturing Method

An article manufacturing method according to an embodiment of the present invention is suitable for manufacturing an article, for example, a microdevice such as a semiconductor device or an element having a microstructure. The article manufacturing method according to this embodiment includes a step of forming a latent image pattern on a photoresist applied to a substrate using the above-described drawing apparatus (step of performing drawing on a substrate), and a step of developing the substrate on which the latent image pattern has been formed in the preceding step. This manufacturing method further includes other known steps (oxidation, deposition, vapor deposition, doping, planarization, etching, resist peeling, dicing, bonding, packaging, and the like). The article manufacturing method according to this embodiment is advantageous in at least one of the performance, quality, productivity, and production cost of an article, as compared to a conventional method.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

In the above description, for example, each of two blanker arrays has been exemplified assuming that it includes the array of an electrode pair that can be driven individually. However, the present invention is not limited this, and each of two blanker arrays may include the array of elements with a blanking function. Each blanker array can include, for example, a reflective electron patterning device as described in U.S. Pat. No. 7,816,655. The device includes a pattern on a top surface, the electron reflective part of the pattern, and the electron non-reflective part of the pattern. The device also includes the array of circuitry configured to dynamically change the electron reflective part and the electron non-reflective part of the above-described pattern using a plurality of pixels that can be controlled independently. Like this, the blanker array may be the array of elements (blankers) which perform blanking of a charged particle beam by changing a reflective part into a non-reflective part to the charged particle beam. Note that it is a matter of course that a charged particle optical system including such reflective device and a charged particle optical system including a transparent device such as the array of the electrode pair can have different arrangements.

This application claims the benefit of Japanese Patent Application No. 2013-205351 filed on Sep. 30, 2013, which is hereby incorporated by reference herein in its entirety.

What is claimed is:

1. A drawing apparatus which performs drawing on a substrate with a plurality of charged particle beams, the apparatus comprising:
two blanker arrays each including a plurality of first blankers which blank a plurality of charged particle beams individually and a plurality of second blankers which blank a plurality of charged particle beams in common;
wherein the plurality of first blankers and the plurality of second blankers in each of the two blanker arrays are arranged such that one of the plurality of charged particle beams passes through corresponding one of the plurality of first blankers of one of the two blanker arrays and corresponding one of the plurality of second blankers of the other of the two blanker arrays.

2. The apparatus according to claim 1, further comprising a controller configured, if the plurality of first blankers in one of the two blanker arrays includes an abnormal blanker, to cause the plurality of second blankers, corresponding to the abnormal blanker, in the other of the two blanker arrays to perform blanking.

3. The apparatus according to claim 2, wherein the controller is configured to control a drawing operation such that drawing is performed, with a charged particle beam which is different from a charged particle beams blanked by the plurality of second blankers corresponding to the abnormal blanker, in a region on the substrate where drawing is not performed by causing the plurality of second blankers corresponding to the abnormal blanker to perform blanking.

4. The apparatus according to claim 2, further comprising a detector configured to detect a charged particle beam that has passed through the two blanker arrays,
wherein the controller is configured to specify the abnormal blanker based on an output from the detector.

5. The apparatus according to claim 1, wherein each of the two blanker arrays includes a first blanker line in which the plurality of first blankers are arrayed along a first direction and a second blanker line in which the plurality of second blankers are arrayed along the first direction, and the first blanker line and the second blanker line are arranged alternately in a second direction intersecting the first direction.

6. The apparatus according to claim 1, wherein in each of the two blanker arrays, one of the plurality of first blankers and one of the plurality of second blankers are arranged alternately along the first direction.

7. The apparatus according to claim 6, wherein the plurality of first blankers are connected with individual signal lines for transmitting control signals thereto, and
the plurality of second blankers are connected with a common signal line for transmitting a control signal thereto.

8. The apparatus according to claim 7, wherein each of the two blanker arrays includes a substrate including the plurality of first blankers and the plurality of second blankers, and signal lines connected to the plurality of first blankers and a signal line connected to the plurality of second blankers are wired in a multilayer wiring structure in the substrate.

9. The apparatus according to claim 1, comprising an aperture member configured to block a charged particle beam deflected by one of the plurality of first blankers or one of the plurality of second blankers.

10. A method of manufacturing an article, the method comprising steps of:
performing drawing on a substrate using a drawing apparatus;
developing the substrate on which the drawing has been performed; and
processing the developed substrate to manufacture the article,
wherein the drawing apparatus performs drawing on the substrate with a plurality of charged particle beams, and includes:
two blanker arrays each including a plurality of first blankers which blank a plurality of charged particle beams individually and a plurality of second blankers which blank a plurality of charged particle beams in common;
wherein the plurality of first blankers and the plurality of second blankers in each of the two blanker arrays are arranged such that one of the plurality of charged particle beams passes through corresponding one of the plurality of first blankers of one of the two blanker arrays and corresponding one of the plurality of second blankers of the other of the two blanker arrays.
